(19) United States
(12) Patent Application Publication
(10) Pub. No.: US 2009/0002952 A1
(43) Pub. Date: Jan. 1, 2009

(54) Interference mitigation

(76) Inventors: Ralph Mesmer, Banks, OR (US); Chaitanya Sreerama, Hillsboro, OR (US); Xiaopeng Dong, Hillsboro, OR (US); Stephen H. Hall, Forest Grove, OR (US)

Correspondence Address: CAVEN & AGHEVLI;c/o INTELLEVATE, LLC, P.O. BOX 52050, MINNEAPOLIS, MN, 55402, US

(21) Appl. No.: 11/823,867

(22) Filed: Jun. 28, 2007

(51) Int. Cl. H05K 7/20; H05K 7/02

(52) U.S. Cl. 361/720; 361/748

(57) ABSTRACT

In some embodiments, an electronic apparatus comprises a display assembly, a printed circuit board comprising a display driver integrated circuit, and at least one structure to alter a resonance frequency characteristic of at least one of the display assembly or the printed circuit board. Other embodiments may be disclosed.

### BACKGROUND

The subject matter described herein relates generally to the field of electronics and more particularly to interference mitigation.

Electromagnetic (EMI) and radio frequency interference (RFI) generated by components of electronic devices such as, e.g., portable computer systems can couple energy into radio chipsets in the electronic devices, which reduces the efficiency of the radio chipsets. In devices such as portable computers that have wireless local area network (LAN) chipsets, the coupled energy increases the noise floor and decreases both the maximum data rate and the effective range of the wireless LAN.

### BRIEF DESCRIPTION OF THE DRAWINGS

The detailed description is described with reference to the accompanying figures.

FIG. 1 is a schematic illustration of an exemplary computing device which may be adapted to implement interference mitigation in accordance with some embodiments.

FIG. 2A is a schematic illustration of a display housing adapted to implement interference mitigation in accordance with some embodiments.

FIG. 2B is a schematic illustration of a display assembly in accordance with some embodiments.

FIG. 3 is a schematic illustration of a display housing adapted to implement interference mitigation in accordance with some embodiments.

FIG. 4 is a flowchart illustrating operations in a method to implement interference mitigation in accordance with some embodiments.

FIG. 5 is a schematic illustration of an interference pattern in accordance with some embodiments.

### DETAILED DESCRIPTION

Described herein are exemplary systems and methods for interference mitigation in electronic devices. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

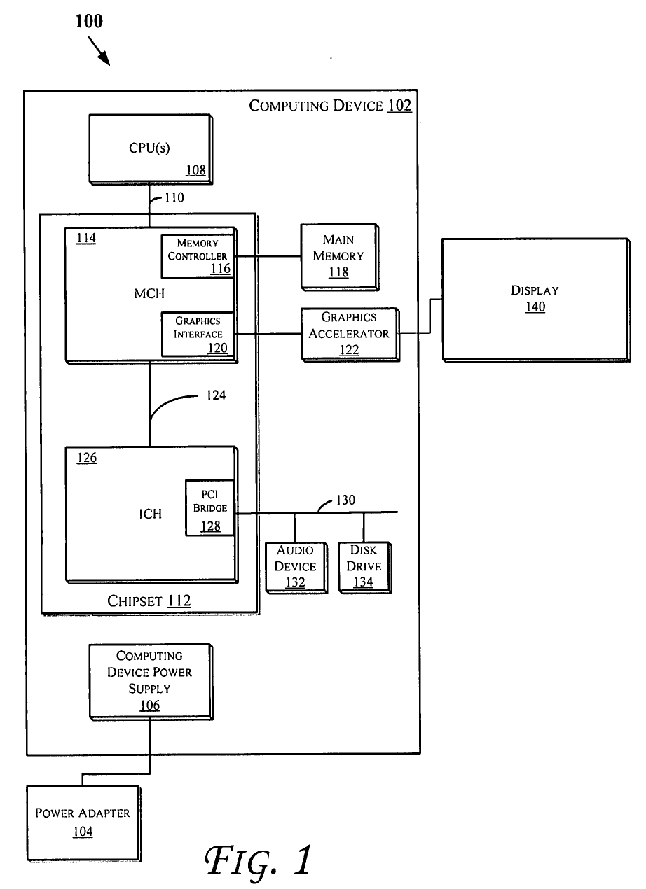

FIG. 1 is a schematic illustration of an exemplary computing device which may be adapted to implement interference mitigation in accordance with some embodiments. The computer system 100 includes a computing device 102 and a power adapter 104 (e.g., to supply electrical power to the computing device 102). The computing device 102 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 102 (e.g., through a computing device power supply 106) from one or more of the following sources: one or more battery packs, an alternating current (AC) outlet (e.g., through a transformer and/or adaptor such as a power adapter 104), automotive power supplies, airplane power supplies, and the like. In some embodiments, the power adapter 104 may transform the power supply source output (e.g., the AC outlet voltage of about 110 VAC to 240 VAC) to a direct current (DC) voltage ranging between about 7 VDC to 12.6 VDC. Accordingly, the power adapter 104 may be an AC/DC adapter.

The computing device 102 may also include one or more central processing unit(s) (CPUs) 108 coupled to a bus 110. In some embodiments, the CPU 108 may be one or more processors in the Pentium® family of processors including, but not limited to, the Pentium® II processor family, Pentium® III processors, Pentium® IV processors available from Intel® Corporation of Santa Clara, Calif. Alternatively, other CPUs may be used, such as Intel's Itanium®, XEON™, and Celeron® processors, or Core™ processors. Also, one or more processors from other manufactures may be utilized. Moreover, the processors may have a single or multi core design.

A chipset 112 may be coupled to the bus 110. The chipset 112 may include a memory control hub (MCH) 114. The MCH 114 may include a memory controller 116 that is coupled to a main system memory 118. The main system memory 118 stores data and sequences of instructions that are executed by the CPU 108, or any other device included in the system 100. In some embodiments, the main system memory 118 includes random access memory (RAM); however, the main system memory 118 may be implemented using other memory types such as dynamic RAM (DRAM), synchronous DRAM (SDRAM), and the like. Additional devices may also be coupled to the bus 110, such as multiple CPUs and/or multiple system memories.

The MCH 114 may also include a graphics interface 120 coupled to a graphics accelerator 122. In some embodiments, the graphics interface 120 is coupled to the graphics accelerator 122 via an accelerated graphics port (AGP). In some embodiments, a display (such as a flat panel display) 140 may be coupled to the graphics interface 120 through, for example, a signal converter that translates a digital representation of an image stored in a storage device such as video memory or system memory into display signals that are interpreted and displayed by the display. The display 140 signals produced by the display device may pass through various control devices before being interpreted by and subsequently displayed on the display.

A hub interface 124 couples the MCH 114 to an input/output control hub (ICH) 126. The ICH 126 provides an interface to input/output (I/O) devices coupled to the computer system 100. The ICH 126 may be coupled to a peripheral component interconnect (PCI) bus. Hence, the ICH 126 includes a PCI bridge 128 that provides an interface to a PCI bus 130. The PCI bridge 128 provides a data path between the CPU 108 and peripheral devices. Additionally, other types of I/O interconnect topologies may be utilized such as the PCI Express™ architecture, available through Intel® Corporation of Santa Clara, Calif.

The PCI bus 130 may be coupled to an audio device 132 and one or more disk drive(s) 134. Other devices may be coupled to the PCI bus 130. In addition, the CPU 108 and the MCH 114 may be combined to form a single chip. Furthermore, the graphics accelerator 122 may be included within the MCH 114 in other embodiments.

Additionally, other peripherals coupled to the ICH 126 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), graphics cards, digital output support (e.g., digital video interface (DVI), high definition multimedia interface (HDMI)), and the like. Hence, the computing device 102 may include volatile and/or nonvolatile memory.

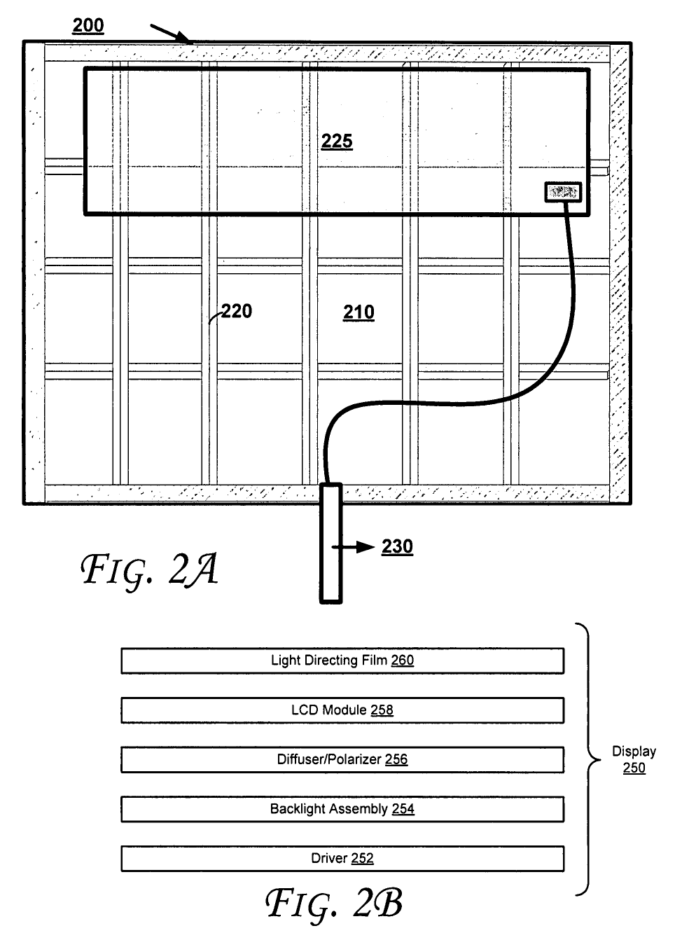

FIG. 2A is a schematic illustration of a display housing 200 adapted to implement interference mitigation in accordance with some embodiments. Referring to FIG. 2A, display housing 200 comprises a panel 210 that comprises a frame 215 to receive a display assembly. Display housing 200 may further include a printed circuit board 225, which may be coupled to a computing device via suitable connector such as a flex connector 230.

In some embodiments, the panel comprises at least one conductive element 220 to alter a resonance frequency characteristic of the panel. In the embodiment depicted in FIG. 2A, the panel comprises a grid of conductive elements 220 which, from an electromagnetic perspective, subdivide the panel into multiple quadrants. Conductive elements 220 reduce electromagnetic resonance in the housing 200. In some embodiments, the conductive elements 220 may be screen printed or ink-jet printed onto the surface of panel 210, or onto an insert attached to panel 210, e.g., using an ink that comprises an electrically conductive material. In some embodiments, conductive elements 220 may be embodied as a stamped mesh conductive material. In some embodiments, conductive elements 220 may be embodied as a rigid grid structure that is mounted to the frame 215 or the panel 210.

In some embodiments the conductive elements 220 may cooperate with at least one heat dissipation element to dissipate heat in the housing. For example, the conductive elements 220 may be positioned in thermal contact with a heat sink, such that the conductive elements 220 function as a heat dissipation component. In one embodiment, at least a portion of the panel 210 may be coated with a thermally conductive material, and the conductive elements may be in thermal communication with the thermally conductive material.

FIG. 2B is a schematic illustration of a display assembly 250 in accordance with some embodiments. Referring to FIG. 2B, a display assembly 250 may comprise a driver 250, which may be implemented as an integrated circuit, a backlight assembly 254, and a diffuser 256, a liquid crystal display (LCD) module 258, and a light directing film 260.

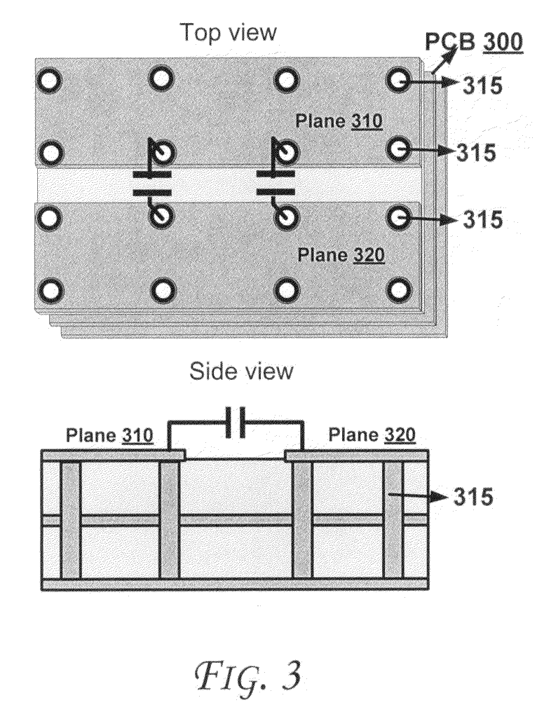

In some embodiments, the printed circuit board on which a display driver resides may be adapted to implement interference mitigation. FIG. 3 is a schematic illustration of a printed circuit board adapted to implement interference mitigation in accordance with some embodiments. The circuit board 300 may correspond to the circuit board 225.

Referring to FIG. 3, in some embodiments, the circuit board 300 may be adapted using one or more techniques, alone or in combination, to mitigate interference. For example, in the printed circuit board 300 depicted in FIG. 3 at least one plane of the circuit board is split into a first plane 310 and a second plane 320. Further, in the printed circuit board 300 depicted in FIG. 3, one or more stitching vias 315 are implemented in the circuit board 300. Further, in the circuit board 300 one or more decoupling capacitors 325 are implemented. These structures, alone or in combination, alter the resonance frequency properties of the printed circuit board such that the resonance frequency is outside the operating frequency range of a radio frequency (RF) integrated circuit assembly which may be used on or proximate the printed circuit board 300.

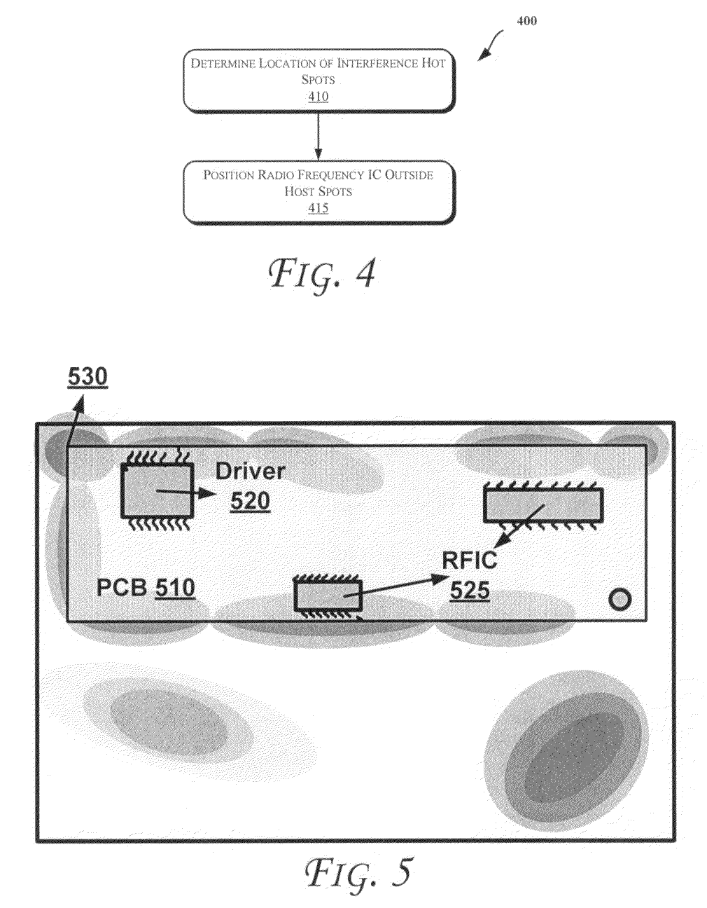

In some embodiments interference may be mitigated by positioning a RF device, memory module or any other IC device that is sensitive to EMI (Electro-Magnetic Interference) outside regions that exhibit high degrees of interference. Regions of high interference may be referred to as “hot spots.” FIG. 4 is a flowchart illustrating operations in a method to implement interference mitigation in accordance with some embodiments.

Referring to FIG. 4, at operation 410 one or more interference hot spots are located. For example, interference hot spots may be located using simulation techniques during a design stage for a printed circuit board that will include an RF device. Alternatively, interference hot spots may be located by testing a prototype device to determine patterns of electromagnetic radiation generated by components of a printed circuit board. In some embodiments interference levels may be mapped onto an image of the circuit board, e.g., using an X-Y coordinate system. At operation 415 a RF device such as an RF integrated circuit (IC) is positioned outside the interference hot spots located in operation 410.

FIG. 5 is a schematic illustration of an interference pattern generated by a printed circuit board 510 that comprises a display driver integrated circuit 520, in accordance with some embodiments. Referring to FIG. 5, regions of high interference (i.e., hot spots) are illustrated by dark regions 530 on the pattern. By contrast, regions of low interference are illustrated by lighter shades on the pattern. Thus, in the embodiment depicted in FIG. 5, the RFIC, memory or any other IC device may be positioned at a location outside a hot spot, as illustrated in FIG. 5.

The terms “logic instructions” as referred to herein relates to expressions which may be understood by one or more machines for performing one or more logical operations. For example, logic instructions may comprise instructions which are interpretable by a processor compiler for executing one or more operations on one or more data objects. However, this is merely an example of machine-readable instructions and embodiments are not limited in this respect.

The terms “computer readable medium” as referred to herein relates to media capable of maintaining expressions which are perceivable by one or more machines. For example, a computer readable medium may comprise one or more storage devices for storing computer readable instructions or data. Such storage devices may comprise storage media such as, for example, optical, magnetic or semiconductor storage media. However, this is merely an example of a computer readable medium and embodiments are not limited in this respect.

The term “logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and embodiments are not limited in this respect.

Some of the methods described herein may be embodied as logic instructions on a computer-readable medium. When executed on a processor, the logic instructions cause a processor to be programmed as a special-purpose machine that implements the described methods. The processor, when configured by the logic instructions to execute the methods described herein, constitutes structure for performing the described methods. Alternatively, the methods described herein may be reduced to logic on, e.g., a field programmable gate array (FPGA), an application specific integrated circuit (ASIC) or the like.

For example, in some embodiments a computer program product may comprise logic instructions stored on a computer-readable medium which, when executed, configure a controller to detect whether a system management memory module is in a visible state, in response to a determination that system management memory is in a visible state, direct one or more system management memory input/output operations to a system management memory module, and in response to a determination that system management memory is in an invisible state, direct system management memory cache write back operations to the system management memory module and direct other system management memory input/output operations to another location in a system memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” or “some embodiments” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An electronic apparatus, comprising:
a display assembly;
a printed circuit board comprising a display driver integrated circuit; and
at least one structure to alter a resonance frequency characteristic of at least one of the display assembly or the printed circuit board.

2. The electronic apparatus of claim 1, further comprising a housing for the display assembly, wherein the housing comprises:
a panel comprising a frame to receive the display assembly; and
at least one conductive element coupled to the panel to alter a resonance frequency characteristic of the panel.

3. The electronic apparatus of claim 2, wherein the at least one conductive element comprises a grid of conductive elements, wherein the grid of conductive comprises at least one of a conductive paint or a stamped mesh material.

4. The electronic apparatus of claim 2, wherein the grid of conductive material comprises a rigid grid structure mounted to the frame.

5. The electronic apparatus of claim 2, wherein:
the panel comprises a heat sink; and
the at least one conductive element is coupled to the heat sink.

6. The electronic apparatus of claim 5, wherein the heat sink comprises a layer of metallic material formed on a surface of the panel.

7. The electronic apparatus of claim 1, wherein the printed circuit board comprises at least one stitching via structure to alter a resonance frequency characteristic of the printed circuit board.

8. The electronic apparatus of claim 1, wherein the printed circuit board comprises at least one decoupling capacitor to alter a resonance frequency characteristic of the printed circuit board.

9. The electronic apparatus of claim 1, wherein the printed circuit board comprises at least one split plane to alter a resonance frequency characteristic of the printed circuit board.

10. A method, comprising:
determining at least one location, on a printed circuit board, of at least one interference hot spot; and
positioning a radio frequency integrated circuit outside the interference hot spot.

11. The method of claim 11, wherein determining at least one location, on a printed circuit board, of at least one interference hot spot comprises simulating electromagnetic signals generated by at least one component on the printed circuit board.

12. The method of claim 11, wherein determining at least one location, on a printed circuit board, of at least one interference hot spot comprises measuring electromagnetic signals generated by a display driver integrated circuit.
